(19) United States
(12) Patent Application Publication
(10) Pub. No.: US 2026/0101581 A1
(43) Pub. Date: Apr. 9, 2026

(54) GATE CONNECTION FOR STACKED TRANSISTORS

(71) Applicant: International Business Machines Corporation, Armonk, NY (US)

(72) Inventors: Kishwar Mashooq, Albany, NY (US); Shay Reboh, Guilderland, NY (US); Takashi Ando, Eastchester, NY (US); Ruilong Xie, Niskayuna, NY (US); Paul Charles Jamison, Averill Park, NY (US)

(21) Appl. No.: 18/910,263

(22) Filed: Oct. 9, 2024

(51) Int. Cl. H01L 27/092; H01L 21/28; H01L 21/822; H01L 21/8238; H01L 23/535; H01L 29/06; H01L 29/423; H01L 29/49; H01L 29/66; H01L 29/775; H01L 29/786

(52) U.S. Cl. CPC H10D 84/856; H10D 30/014; H10D 30/43; H10D 30/6735; H10D 30/6739; H10D 30/6757; H10D 62/121; H10D 64/01318; H10D 84/0177; H10D 84/0186; H10D 84/038; H10D 88/01; H10W 20/20

(57) ABSTRACT

Embodiments disclose a gate connection for stacked transistors. A semiconductor structure includes an upper transistor having a first work function material disposed over a lower transistor having a second work function material. The semiconductor structure includes a gate connection connecting the first work function material to the second work function material, the gate connection comprising a liner formed of the second work function material.

### BACKGROUND

The present invention generally relates to fabrication methods and resulting structures for integrated circuits (ICs), and more specifically, to fabrication methods and resulting structures configured and arranged to provide a gate connection for sequentially stacked transistors.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer, on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device for advanced integrated circuit products is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to implementing a gate connection for sequentially stacked transistors. A semiconductor structure includes an upper transistor having a first work function material disposed over a lower transistor having a second work function material, and a gate connection connecting the first work function material to the second work function material, the gate connection having a liner formed of the second work function material.

According to one or more embodiments, a method includes providing an upper transistor having a first work function material disposed over a lower transistor having a second work function material and forming a gate connection connecting the first work function material to the second work function material. The gate connection includes a liner formed of the second work function material.

According to one or more embodiments, a method includes forming an upper transistor and a lower transistor with a sacrificial material, the upper transistor being over the lower transistor, and annealing the upper and lower transistors. The method includes replacing the sacrificial material of the upper transistor with a first work function material and forming a trench exposing a sidewall of the first work function material and a portion of the sacrificial material of the lower transistor. The method includes replacing the sacrificial material of the lower transistor with a second work function material, so as to form a liner of the second work function material in the trench and filling the trench with a fill material.

According to one or more embodiments, a semiconductor structure includes an upper transistor having a first work function material disposed over a lower transistor having a second work function material, and a gate connection connecting the upper transistor to the lower transistor, the gate connection having a liner formed of the second work function material and a fill material. The liner intervenes between the first work function material and the fill material, where the fill material includes a conductive material or a dielectric material.

According to one or more embodiments, a method includes forming an upper transistor having a first work function material, forming a lower transistor having a second work function material disposed below the upper transistor, and forming a gate connection connecting the upper transistor to the lower transistor, the gate connection having a liner formed of the second work function material and a fill material. The liner intervenes between the first work function material and the fill material, where the fill material includes a conductive material or a dielectric material.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A, 1B, 1C, and 1D respectively depict cross-sectional views of semiconductor structures having gate connections according to one or more embodiments;

FIGS. 2A, 2B, 2C, and 2D respectively depict cross-sectional views of semiconductor structures having gate connections according to one or more embodiments;

FIGS. 3A, 3B, 3C, and 3D respectively depict cross-sectional views of semiconductor structures having gate connections according to one or more embodiments;

FIGS. 4A, 4B, 4C, and 4D respectively depict cross-sectional views of semiconductor structures having gate connections according to one or more embodiments;

FIG. 5 depicts a flowchart of a method of forming a semiconductor structure according to one or more embodiments;

FIGS. 6A, 6B, 6C, 6D, 6E, 6F, and 6G depict fabrication operations of forming a semiconductor structure according to one or more embodiments;

FIGS. 7A, 7B, and 7C depict examples of gate connection openings with a liner according to one or more embodiments;

FIG. 8 depicts a flowchart of a method of forming a semiconductor structure according to one or more embodiments;

FIG. 9 depicts a flowchart of a method of forming a semiconductor structure according to one or more embodiments; and

FIG. 10 depicts a flowchart of a method of forming a semiconductor structure according to one or more embodiments.

### DETAILED DESCRIPTION

Embodiments of the present disclosure are directed to a semiconductor structure. The semiconductor structure includes an upper transistor having a first work function material disposed over a lower transistor having a second work function material, and a gate connection connecting the first work function material to the second work function material. The gate connection includes a liner formed of the second work function material. As technical effects and solutions, by integrating the gate connection with a liner of the second work function material, the structure supports a single reliability anneal process for both transistors. This reduces thermal stress and potential degradation of the lower transistor, which is particularly beneficial for thermally sensitive p-type transistor devices. Consequently, this enhances the reliability and longevity of the semiconductor device.

In addition to one or more of the features described above or below, or as an alternative, further embodiments disclose the liner of the gate connection is in contact with a sidewall of the first work function material. Technical effects and solutions include enhancing electrical connectivity and stability between the upper and lower transistors. This contact ensures a robust and reliable electrical path, reducing resistance and improving signal integrity.

In addition to one or more of the features described above or below, or as an alternative, further embodiments disclose the liner extends a height of the first work function material. Technical effects and solutions ensure comprehensive electrical contact along the entire vertical dimension of the transistor.

In addition to one or more of the features described above or below, or as an alternative, further embodiments disclose the liner extends a partial height of the first work function material. Technical effects and solutions allow for optimized electrical connectivity while reducing material usage. This design can decrease parasitic capacitance.

In addition to one or more of the features described above or below, or as an alternative, further embodiments disclose the liner extends from the lower transistor to the upper transistor. Technical effects and solutions facilitate seamless electrical integration between the two transistors.

In addition to one or more of the features described above or below, or as an alternative, further embodiments disclose the gate connection includes a fill material different from the second work function material. Technical effects and solutions allow for tailored electrical properties within the semiconductor structure.

In addition to one or more of the features described above or below, or as an alternative, further embodiments disclose the gate connection incudes a fill material different from the second work function material, the fill material being a conductive material. Technical effects and solutions allow for tailored electrical properties within the semiconductor structure.

In addition to one or more of the features described above or below, or as an alternative, further embodiments disclose the lower transistor includes fill material disposed around a combination of channel regions and a portion of the second work function material. Technical effects and solutions reduce gate resistance.

In addition to one or more of the features described above or below, or as an alternative, further embodiments disclose the gate connection includes a fill material different from the second work function material, the fill material being a dielectric material. Technical effects and solutions reduce the parasitic capacitance of the gate connection.

Embodiments disclose a method including providing an upper transistor having a first work function material disposed over a lower transistor having a second work function material and forming a gate connection connecting the first work function material to the second work function material. The gate connection includes a liner formed of the second work function material. As technical effects and solutions, by integrating the gate connection with a liner of the second work function material, the structure supports a single reliability anneal process for both transistors. This reduces thermal stress and potential degradation of the lower transistor, which is particularly beneficial for thermally sensitive p-type transistor devices. Consequently, this enhances the reliability and longevity of the semiconductor device.

In addition to one or more of the features described above or below, or as an alternative, further embodiments disclose the liner of the gate connection is in contact with a sidewall of the first work function material. Technical effects and solutions include enhancing electrical connectivity and stability between the upper and lower transistors. This contact ensures a robust and reliable electrical path, reducing resistance and improving signal integrity.

In addition to one or more of the features described above or below, or as an alternative, further embodiments disclose the liner extends a height of the first work function material. Technical effects and solutions ensure comprehensive electrical contact along the entire vertical dimension of the transistor.

In addition to one or more of the features described above or below, or as an alternative, further embodiments disclose the liner extends a partial height of the first work function material. Technical effects and solutions allow for optimized electrical connectivity while reducing material usage. This design can decrease parasitic capacitance.

In addition to one or more of the features described above or below, or as an alternative, further embodiments disclose the liner extends from the lower transistor to the upper transistor. Technical effects and solutions facilitate seamless electrical integration between the two transistors.

In addition to one or more of the features described above or below, or as an alternative, further embodiments disclose the gate connection includes a fill material different from the second work function material. Technical effects and solutions allow for tailored electrical properties within the semiconductor structure.

In addition to one or more of the features described above or below, or as an alternative, further embodiments disclose the gate connection incudes a fill material different from the second work function material, the fill material being a conductive material. Technical effects and solutions allow for tailored electrical properties within the semiconductor structure.

In addition to one or more of the features described above or below, or as an alternative, further embodiments disclose the lower transistor includes fill material disposed around a combination of channel regions and a portion of the second work function material. Technical effects and solutions reduce gate resistance.

In addition to one or more of the features described above or below, or as an alternative, further embodiments disclose the gate connection includes a fill material different from the second work function material, the fill material being a dielectric material. Technical effects and solutions reduce the parasitic capacitance of the gate connection.

Embodiments disclose a method including forming an upper transistor and a lower transistor with a sacrificial material, the upper transistor being over the lower transistor, annealing the upper and lower transistors, and replacing the sacrificial material of the upper transistor with a first work function material. The method includes forming a trench exposing a sidewall of the first work function material and a portion of the sacrificial material of the lower transistor, replacing the sacrificial material of the lower transistor with a second work function material, so as to form a liner of the second work function material in the trench, and filling the trench with a fill material. Technical effects and solutions allow for precise control over the work function materials. The process of annealing both transistors simultaneously reduces thermal stress and potential degradation, which is particularly beneficial for thermally sensitive devices.

In addition to one or more of the features described above or below, or as an alternative, further embodiments disclose the liner of the trench is in contact with the sidewall of the first work function material. Technical effects and solutions enhance the electrical connection between the upper and lower transistors.

In addition to one or more of the features described above or below, or as an alternative, further embodiments disclose the liner extends a height of the first work function material or the liner extends a partial height of the first work function material, and the liner extends from the lower transistor to the upper transistor. Technical effects and solutions ensure comprehensive electrical contact along the vertical dimension of the transistor.

In addition to one or more of the features described above or below, or as an alternative, further embodiments disclose the fill material is different from the second work function material, the fill material being a conductive material or a dielectric material. Technical effects and solutions allow for tailored electrical properties within the semiconductor structure.

In addition to one or more of the features described above or below, or as an alternative, further embodiments disclose the lower transistor includes the fill material disposed around a combination of channel regions and a portion of the second work function material. Technical effects and solutions reduce gate resistance.

Embodiments disclose a semiconductor structure including an upper transistor having a first work function material disposed over a lower transistor having a second work function material. The semiconductor structure includes a gate connection connecting the upper transistor to the lower transistor, the gate connection including a liner formed of the second work function material and a fill material, the liner intervening between the first work function material and the fill material, where the fill material comprises a conductive material or a dielectric material. Technical effects and solutions allow for control over the work function materials with a gate connection including a liner of the second work function material. The use of a fill material, which can be either conductive or dielectric, allows for tailored electrical properties, optimizing the device's performance.

Embodiments disclose a method of forming a semiconductor structure. The method includes forming an upper transistor having a first work function material and forming a lower transistor having a second work function material disposed below the upper transistor. The method includes forming a gate connection connecting the upper transistor to the lower transistor, the gate connection having a liner formed of the second work function material and a fill material, the liner intervening between the first work function material and the fill material, where the fill material includes a conductive material or a dielectric material. Technical effects and solutions allow for control over the work function materials with a gate connection including a liner of the second work function material. The use of a fill material, which can be either conductive or dielectric, allows for tailored electrical properties, optimizing the device's performance.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

Another nonplanar transistor architecture is the so-called stacked field effect transistor (FET). To increase the available computing power per unit area, a stacked FET (or SFET) includes a vertical stack of two (or more) FETs over a shared substrate footprint. As one fabrication technique, two wafers are processed separately (i.e., semiconductor stacks are built on each wafer) and later joined via a wafer bonding process. The resultant stacked transistor architecture offers several improvements over planar and fin-type devices, such as the ability to build complementary devices (e.g., CMOS) at a reduced footprint.

One or more embodiments improve fabrication methods and resulting structures for stacked FETs by using a gate connection for sequentially stacked transistors. By forming the gate connection between the upper and lower transistors in accordance with one or more embodiments, this allows a single reliability anneal to be performed for both the upper and lower transistors. This has the technical effect and solution of allowing a PFET device to be formed as the lower transistor while an NFET device is the upper transistor, such that the lower transistor is not negatively affected by multiple anneals because a single reliability anneal is performed. A PFET may have thermal sensitivity, and multiple anneals are avoided. Further, different work function materials can be utilized in the upper and lower transistors, such that the work function material of the lower transistor is not affected by previous fabrication steps. This can result in transistors with different threshold voltages. Further, the gate connection between the upper and lower transistors is formed with a liner of the bottom work function material/metal.

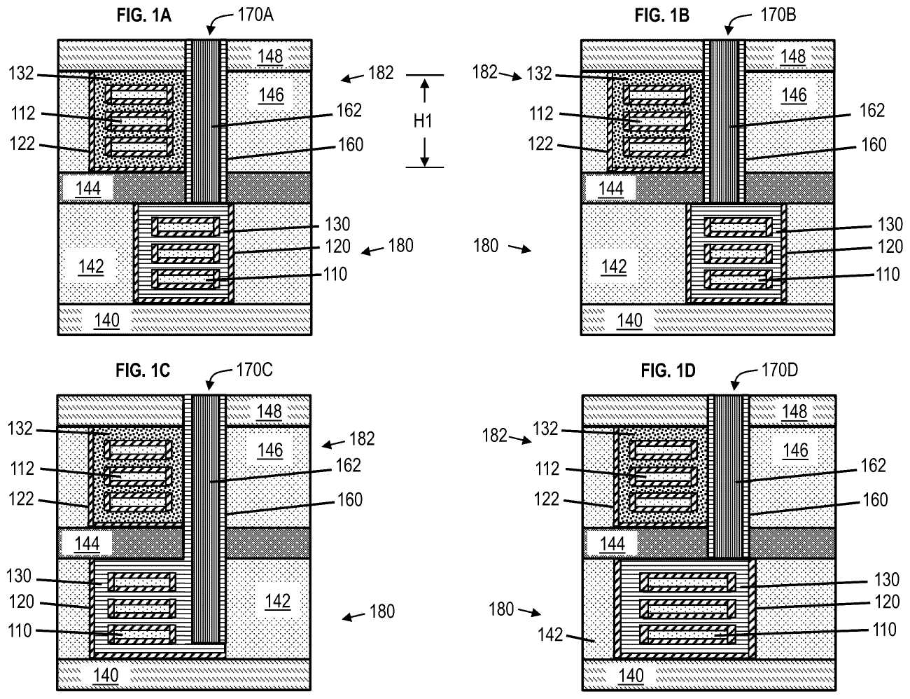

Turning now to a more detailed description of aspects of the present invention, FIGS. 1A, 1B, 1C, and 1D depict cross-sectional views of semiconductor structures. The semiconductor structures are stacked transistors. FIG. 1A depicts stacked transistors in a shifted active region structure according to one or more embodiments. FIG. 1B depicts stacked transistors in a staggered structure according to one or more embodiments. FIG. 1C depicts stacked transistors in an I-shaped stacked transistor structure according to one or more embodiments. FIG. 1D depicts stacked transistors in an L-shaped stacked transistor structure according to one or more embodiments.

FIGS. 1A, 1B, 1C, 1D, and 1E depict semiconductor structures where several known fabrication processes have been performed. Any suitable lithography processes including deposition techniques and etching techniques can be utilized herein. An upper transistor 182 is formed above a lower transistor 180. The lower transistor 180 includes semiconductor layers 110 as channel regions. High-k dielectric material 120 is formed to wrap around the semiconductor layers 110. Bottom work function material 130 is formed around the high-k dielectric material 120. The lower transistor 180 is on an underlayer 140, which can be a nitride material such as, for example, silicon nitride, etc. The lower transistor 180 can have spacer material 142 on the sides. Example materials of the spacer material may include SiN, SiBCN, SiOCN, SiOC, etc.

The upper transistor 182 includes semiconductor layers 112 as channel regions. High-k dielectric material 122 is formed to wrap around the semiconductor layers 112. Top work function material 132 is formed around the high-k dielectric material 122. The top work function material 132 can be n-type materials for an NFET, while the bottom work function material 130 can be p-type materials for a PFET, or vice versa.

The upper transistor 182 is on a bonding layer 144, which can be an oxide material such as, for example, silicon dioxide, etc. The upper transistor 182 can have spacer material 146 on the sides. Example materials of the spacer material may include SiN, SiBCN, SiOCN, SiOC, etc. An upper layer 148 can be above the lower transistor 180 and upper transistor 182. The upper layer 148 can be formed on a nitride material such as, for example, silicon nitride, etc. The

Gate connections 170A, 170B, 170C, and 170D are respectively illustrated in the semiconductor structures of FIGS. 1A, 1B, 1C, and 1D. Gate connections 170A, 170B, 170C, and 170D have different structures and connect the lower transistor 180 to the upper transistor 182, thereby providing shared gate control. The gate connections 170A, 170B, 170C, and 170D can generally be referred to as gate connections 170. In one or more embodiments, the gate connections 170 can have different positions relative to the upper and lower transistors, different heights in the vertical direction, different connections to the lower transistor, etc. Each of the gate connections 170 includes a conductive liner 160 formed of the same material of the bottom work function material 130 of the lower transistor 180. The gate connections 170 are filled with a (conductive) fill material 162 such that the conductive liner 160 lines the (conductive) fill material 162. The (conductive) fill material 162 is a different material from the conductive liner 160. Example materials of the (conductive) fill material 162 may include tungsten, titanium, titanium nitride, aluminum, nickel, chromium, copper, gold, etc., along with various combinations.

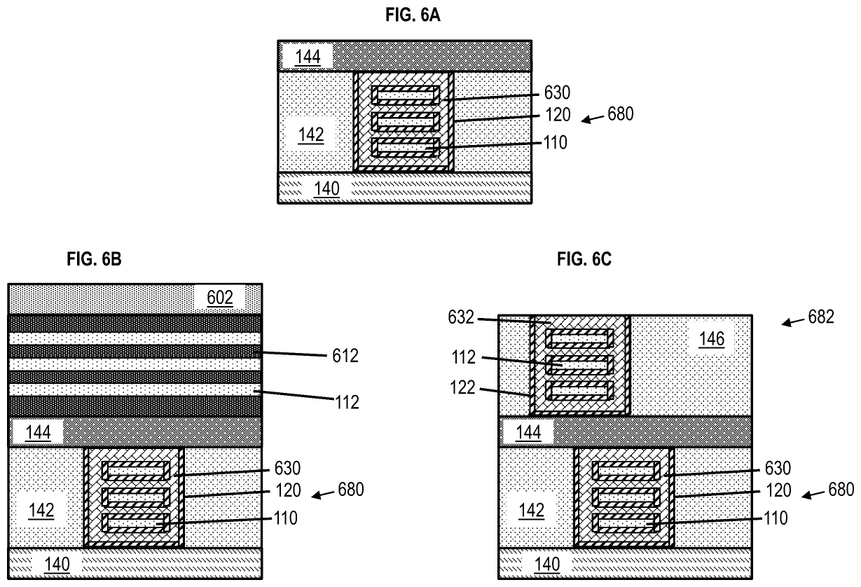

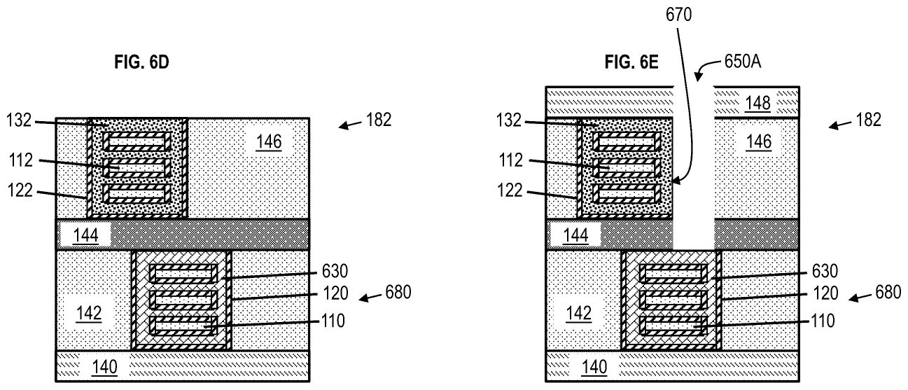

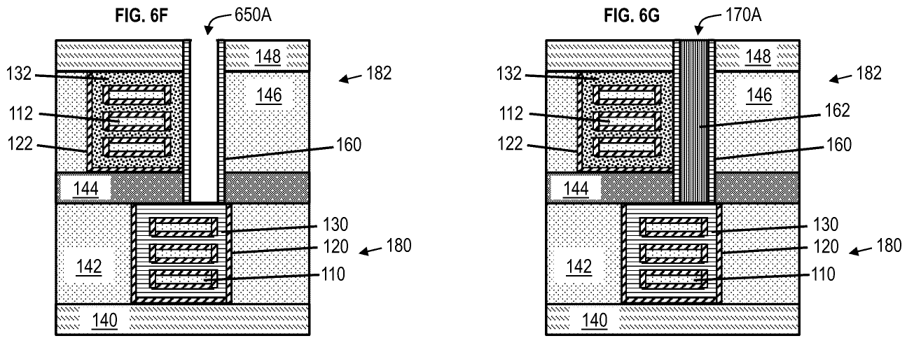

In FIGS. 1A, 1B, 1C, and 1D, the bottom work function material 130 is in contact with the top work function material 132. Particularly, a portion of the outer liner of (top) high-k dielectric material 122 is removed such that the conductive liner 160 formed of top work function material 132 is in direct contact with the top work function material 132. In FIGS. 1A, 1B, 1C, and 1D, the gate connections 170 are formed on an exposed sidewall (e.g., sidewall 670 depicted in FIG. 6E) of the top work function material 132. In FIGS. 1A, 1B, and 1D, the gate connections 170 extends from a top surface of the bottom work function material 130 up along the sidewall of the top work function material 132. In FIG. 1C, the gate connection 170C extends from within the bottom work function material 130 up along the sidewall of the top work function material 132. In FIGS. 1A, 1B, 1C, and 1D, the gate connections 170 extend up through the upper layer 148 so as to be available for other connections.

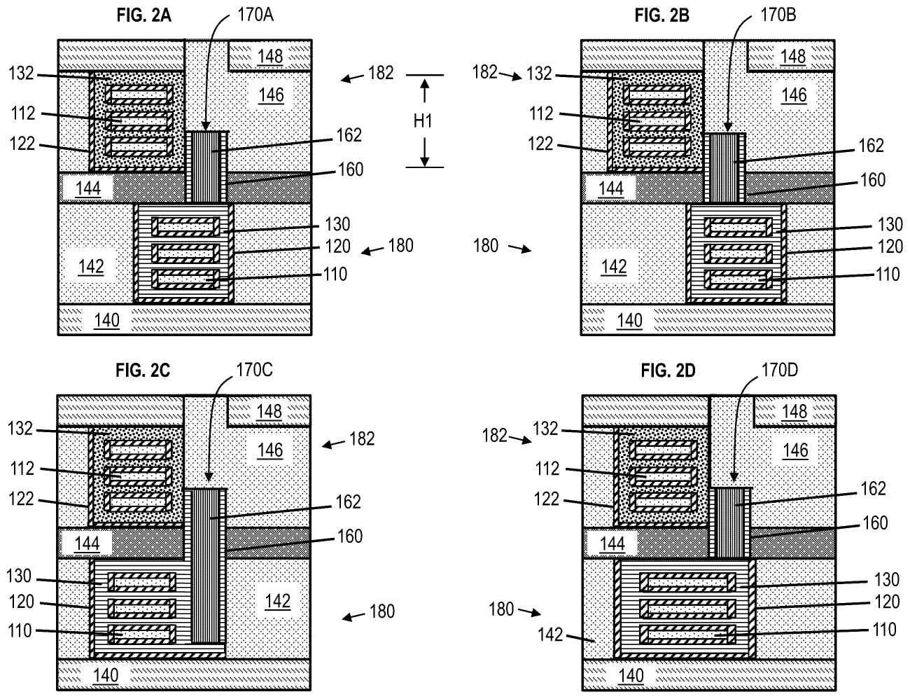

FIGS. 2A, 2B, 2C, and 2D depict cross-sectional views of semiconductor structures according to one or more embodiments. Some details of FIGS. 2A, 2B, 2C, and 2D are respectively analogous to FIGS. 1A, 1B, 1C, and 1D. In FIGS. 2A, 2B, 2C, and 2D, the gate connections 170 have a shortened height in the vertical direction. In one or more embodiments, the gate connections 170 may extend up from the lower transistor 180 along the sidewall of the upper transistor 182 stopping about midway, less than midway, etc., of the upper transistor 182. In one or more embodiments, the gate connections 170 can extend up above the midway of the upper transistor but less than the entirety of the sidewall of the upper transistor 182 in the vertical direction. The reduced height of the gate connections 170 in FIGS. 2A, 2B, 2C, and 2D can provide a reduced capacitance for the gate connections 170.

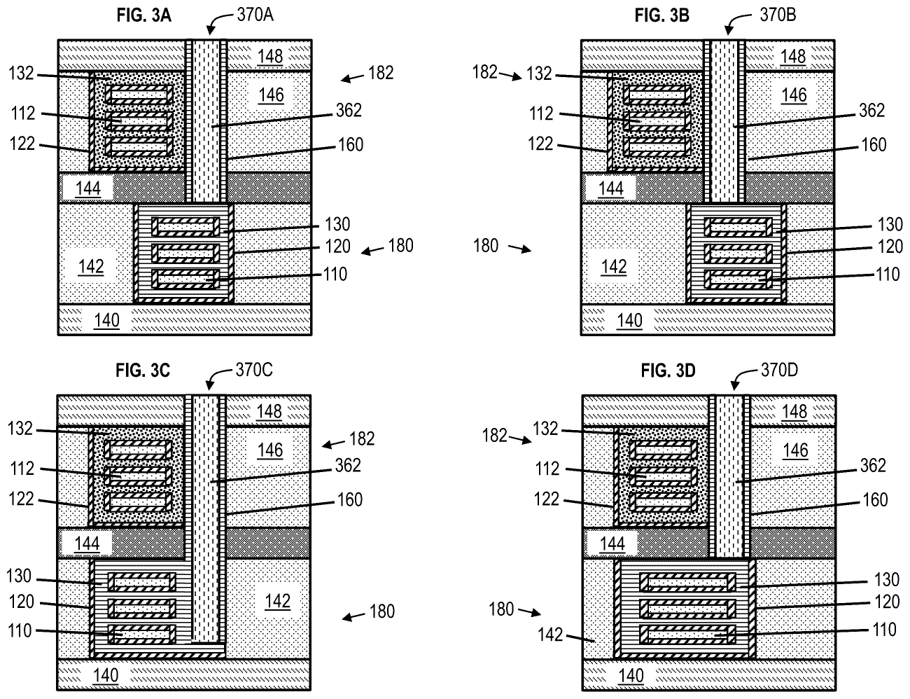

FIGS. 3A, 3B, 3C, and 3D depict cross-sectional views of semiconductor structures according to one or more embodiments. Some details of FIGS. 3A, 3B, 3C, and 3D are respectively analogous to FIGS. 1A, 1B, 1C, and 1D. In FIGS. 3A, 3B, 3C, and 3D, the gate connections 370A, 370B, 370C, and 370D are filled with (dielectric) fill material 362 as fill material instead of (conductive) fill material 162 in FIGS. 1A, 1B, 1C, and 1D. This serves to reduce the capacitance of the gate connections 370A, 370B, 370C, and 370D, even though the gate connections 370A, 370B, 370C, and 370D extend from the lower transistor 180 up along the entire sidewall of the top work function material 132 of the upper transistor 182. The (dielectric) fill material 362 is lined with the conductive liner 160 in order to provide the electrical connection between the top work function material 132 and the bottom work function material 130. Example materials of the dielectric material of the fill material 362 can include low-k dielectric materials, ultra-low-k dielectric materials, etc. Although not shown, the gate connections 170 depicted in FIGS. 2A, 2B, 2C, and 2D can have dielectric material in place of the conductive material, in accordance with one or more embodiments. The gate connections 370A, 370B, 370C, and 370D can generally be referred to as gate connections 370.

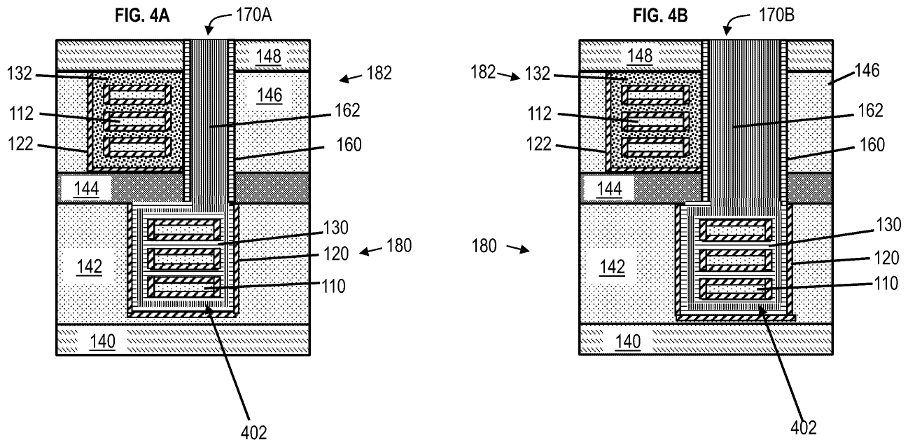

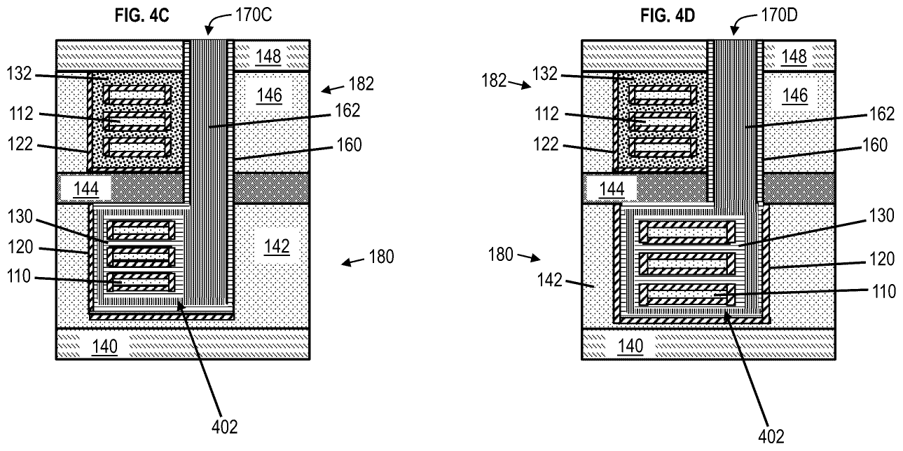

FIGS. 4A, 4B, 4C, and 4D depict cross-sectional views of semiconductor structures according to one or more embodiments. Some details of FIGS. 4A, 4B, 4C, and 4D are respectively analogous to FIGS. 1A, 1B, 1C, and 1D.

In FIGS. 4A, 4B, 4C, and 4D, the size of the lower transistor 180 is large enough to accommodate conductive material of the fill material 162. For example, FIGS. 4A, 4B, 4C, and 4D respectively include surrounding structures 402 of the (conductive) fill material 162. The surrounding structures 402 surround the semiconductor layers 110 and a portion of the bottom work function material 130 in the lower transistor 180. The surrounding structures 402 may act as a metal fill in the lower transistor 180. In one or more embodiments, the surrounding structures 402 can be sandwiched between two layers of the bottom work function material 130 in the lower transistor 180. In one or more embodiments, the bottom work function material 130 encapsulates the semiconductor layers 110 and high-k dielectric materials that wraps around the semiconductor layers 110, while being surrounded by the surrounding structure 402 which is surrounded by a thin layer of the bottom work function material 130. The (conductive) fill material 162 of the gate connections 170 connect to the surrounding structures 402 and extend up along the sidewall of the upper transistor 182. The surrounding structures 402 serve to reduce the gate resistance of the lower transistor 180. Depending on the fabrication process, there may be portion of the surrounding structures 402 that has a gap or opening.

Although not shown, the gate connections 170 depicted in FIGS. 2A, 2B, 2C, and 2D can have surrounding structures 402 of (conductive) fill material 162, in accordance with one or more embodiments.

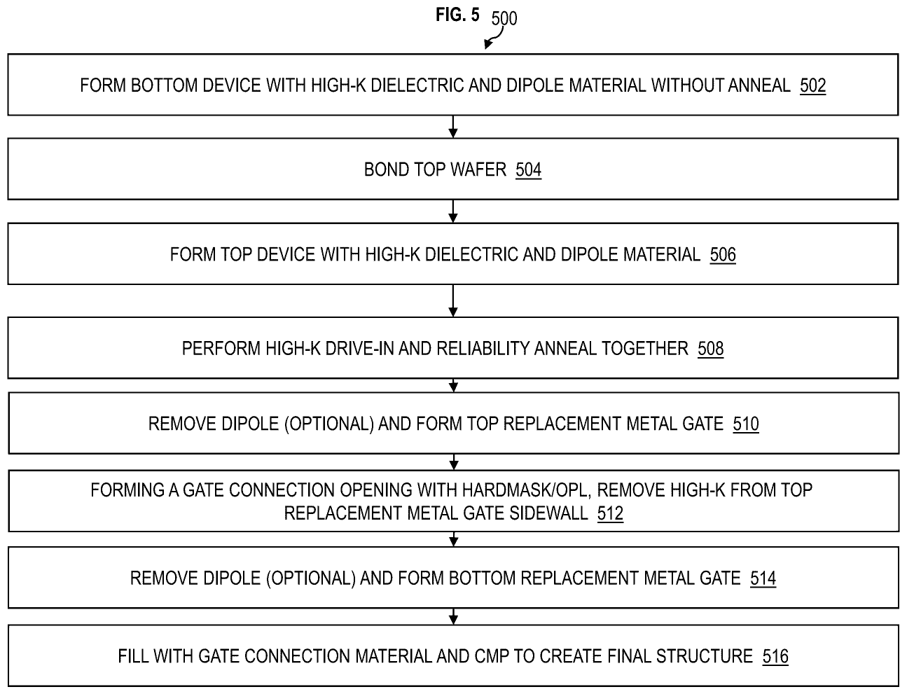

FIG. 5 depicts a flowchart of a computer-implemented method 500 of forming a semiconductor structure with a gate connection between stacked transistors in accordance with one or more embodiments. Reference can be made to any of the figures discussed herein. According to one or more embodiments, FIGS. 6A, 6B, 6C, 6D, 6E, 6F, and 6G depict graphical representations of the fabrication process of FIG. 5.

At block 502, the method 500 includes forming a bottom device 680 with semiconductor layers 110, high-k dielectric material 120, and sacrificial material 630. Various materials can be utilized for the high-k dielectric material 120. In one or more embodiments, examples of the high-k dielectric material 120 can include lanthanum oxide (LaOₓ) and aluminum oxide (AlOₓ), as optional dipole materials. The sacrificial material 630 serves as a fill material formed on the high-k dielectric material 120. The sacrificial material 630 may be a stack of materials. The sacrificial material 630 can include titanium nitride (TiN) with amorphous silicon (a-Si) formed/stacked on top of the TiN material. The amorphous silicon may be formed as a cap. In one or more embodiments, the sacrificial material 630 can include TiAlC and TiN with a-Si on top as the cap. Chemical mechanical polishing/planarization (CMP) can be performed to polish away any excess material. An example is depicted in FIG. 6A.

At block 504, the method 500 includes bonding a top wafer to the structure. The top wafer 602 can include alternating nanosheets of semiconductor layers 112 and sacrificial layers 612. The semiconductor layers 112 may be formed of silicon or other semiconductor materials, and the sacrificial layers 612 may be formed of silicon germanium. The upper layer 148 is formed on top. An example is depicted in FIG. 6B.

At block 506, the method 500 includes forming a top device 682 with a high-k dielectric material 122 and sacrificial material 632, after removing the top wafer 602 (e.g., by grinding/polishing). Various materials can be utilized for the high-k dielectric material 122. In one or more embodiments, examples of the high-k dielectric material 122 can include lanthanum oxide and aluminum oxide, as optional dipole material. As discussed herein, the sacrificial material 632 serves as a fill material formed on the high-k dielectric material 122. The sacrificial material 632 may be a stack of materials. The sacrificial material 632 can include titanium nitride with amorphous silicon formed/stacked on top of the TiN material. The amorphous silicon may be formed as a cap. CMP can be performed to polish away any excess material. An example is depicted in FIG. 6C. Although FIG. 6C depicts a representation of stacked transistors in a shifted active region structure, it should be appreciated that FIGS. 5 and 6A-6G apply to stacked transistors in any configuration including a staggered structure, an I-shaped stacked transistor structure, and an L-shaped stacked transistor structure according to one or more embodiments.

At block 508, the method 500 includes performing high-k drive-in anneal and reliability anneal concurrently. The high-k drive-in anneal drives in the dipoles, while the reliability anneal cures any defects. An example is depicted in FIG. 6C.

A technical benefit is that the drive-in anneal for the high-k dielectric material 120 and the high-k dielectric material 122 can be performed (only) once, for both the upper and lower transistors.

At block 510, the method 500 includes performing a replacement metal gate (RMG) process by removing the sacrificial material 632, filling the opening with top work function material 132, and performing CMP. An example is depicted in FIG. 6D.

In one or more embodiments, the stack of the sacrificial material 632 (as well as the sacrificial material 630) can be a TiN/a-Si stack. In one or more embodiments, an ammonia wet etch can be utilized to remove the amorphous silicon material, and a Standard Clean 1 (SC1) etch can be utilized to remove the titanium nitride material. A patterned organic planarization layer (OPL) can protect the semiconductor structure during the etching process.

At block 512, the method 500 includes forming a gate connection opening.

The upper layer 148 can be formed to serve as a hardmask, and an organic planarization layer (OPL) can be formed on top and patterned. Etching can be performed to form gate connection opening 650A in preparation for the gate connection. A reactive ion etch (RIE) and a wet etch can be utilized to form the gate connection opening 650A. The etching removes a sidewall of the high-k dielectric material 122 in order to expose the top work function material 132 of the upper transistor 182. Also, the etching exposes a portion of the bottom device 680 in preparation for the replacement metal gate process. As an example, the high-k dielectric material 122 can be etched using a dilute hydrofluoric acid (DHF) based wet etchant. In one example, DHF and hydrochloric acid (HCl) can be utilized in the process flow. Also, hydrofluoric acid can be utilized to etch oxides. An example is depicted in FIG. 6E.

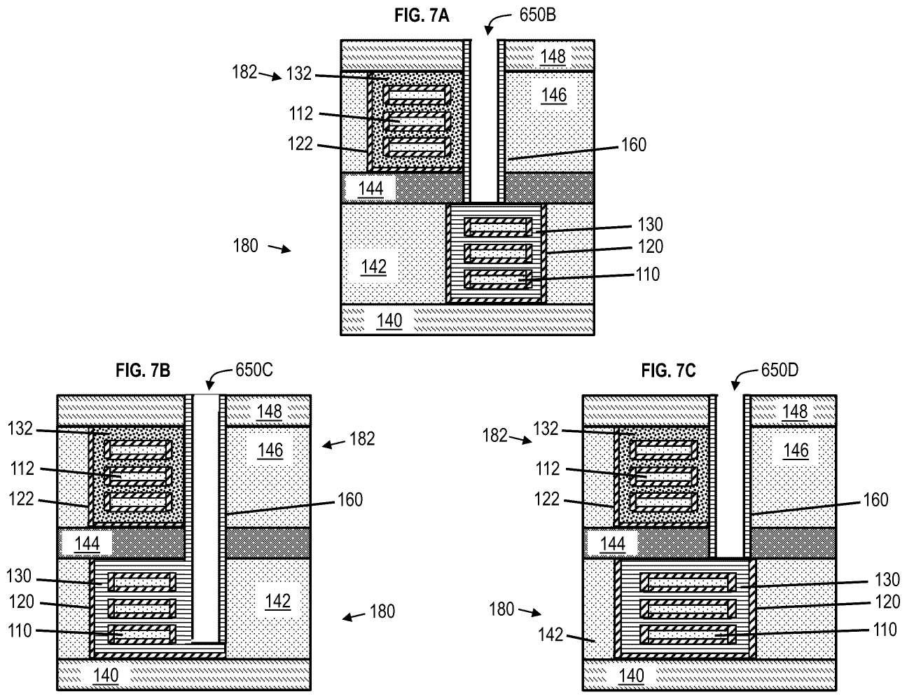

At block 514, the method 500 includes performing a replacement metal gate (RMG) process by removing the sacrificial material 630 of the bottom device 680, filling the opening with bottom work function material 130, and performing CMP. This results in the lower transistor 180 and concurrently forms the conductive liner 160 of the bottom work function material 130 in the gate connection opening 650A. An example is depicted in FIG. 6F. Further examples of forming gate connection openings 650B, 650C, and 650D with conductive liners 160 for stacked transistors having a staggered structure, an I-shaped stacked transistor structure, and an L-shaped stacked transistor structure are respectively illustrated in FIGS. 7A, 7B, and 7C.

At block 516, the method 500 includes filling the gate connection opening with gate connection material and performing CMP. For example, the gate connection opening 650A is filled with the (conductive) fill material 162 and CMP is performed, thereby forming the gate connection 170A as depicted in FIG. 6G. Likewise, the gate connection openings 650B, 650C, and 650D of FIGS. 7A, 7B, and 7C are filled with (conductive) fill material 162. In one or more embodiments, the gate connection openings can be filled with dielectric material, resulting in the semiconductor structures depicted in FIGS. 3A, 3B, 3C, and 3D.

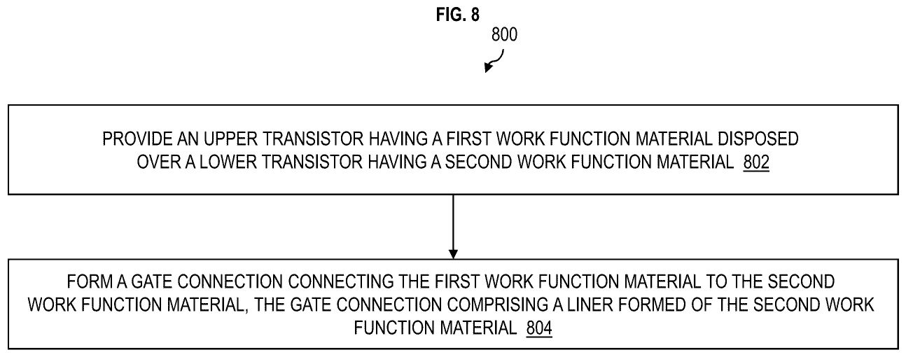

FIG. 8 is a flowchart of a computer-implemented method 800 of forming a semiconductor structure with stacked transistors having a gate connection according to one or more embodiments. Reference can be made to any figures discussed herein.

At block 802, the method 800 includes providing an upper transistor 182 having a first work function material (e.g., top work function material 132) disposed over a lower transistor 180 having a second work function material (e.g., bottom work function material 130). At block 804, the method includes forming a gate connection (e.g., gate connections 170 and 370) connecting the first work function material to the second work function material, the gate connection comprising a liner (e.g., conductive liner 160) formed of the second work function material (e.g., bottom work function material 130).

The liner (e.g., conductive liner 160) of the gate connection is in contact with a sidewall 670 of the first work function material. The liner (e.g., conductive liner 160) extends a height (e.g., encompasses the height H1) of the first work function material.

The liner (e.g., conductive liner 160) extends a partial height (e.g., does not encompass the entire height H1) of the first work function material. The liner (e.g., conductive liner 160) extends from the lower transistor 180 to the upper transistor 182.

The gate connection 170 and 370 include a fill material 162 and 362 different from the second work function material (e.g., bottom work function material 130). The gate connection includes a fill material 162 different from the second work function material, the fill material 162 being a conductive material. The lower transistor 180 includes fill material (e.g., surrounding structures 402 of fill material 162) disposed around a combination of channel regions (e.g., formed of semiconductor layers 110) and a portion of the second work function material (e.g., bottom work function material 130). Examples are depicted in FIGS. 4A, 4B, 4C, and 4D. The gate connection 370 includes a fill material 362 different from the second work function material (e.g., bottom work function material 130), the fill material 362 being a dielectric material. Examples are depicted in FIGS. 3A, 3B, 3C, and 3D.

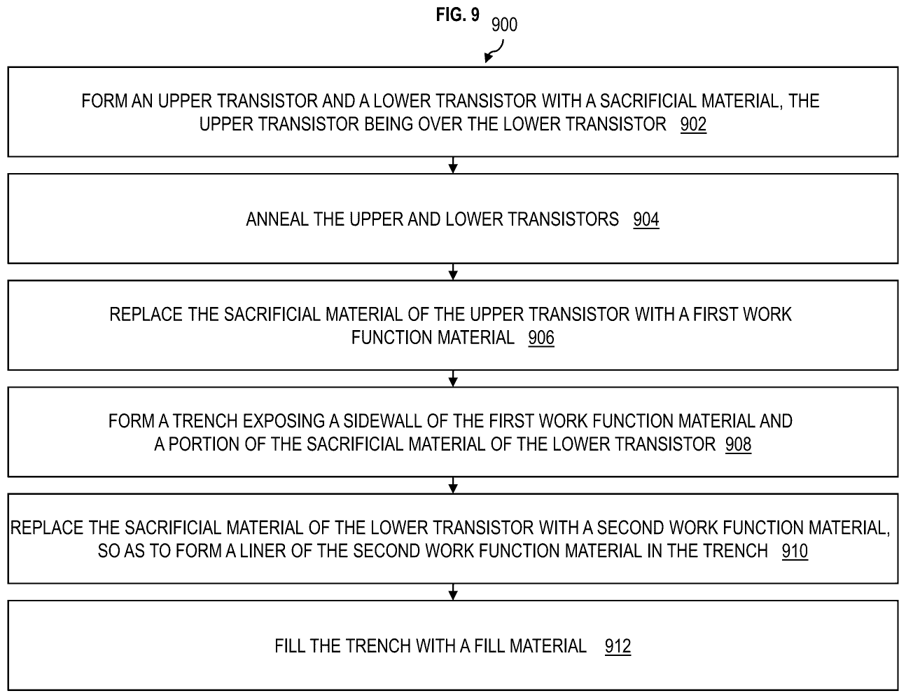

FIG. 9 a flowchart of a computer-implemented method 900 of forming a semiconductor structure with stacked transistors having a gate connection according to one or more embodiments. Reference can be made to any figures discussed herein.

At block 902, the method 900 includes forming an upper transistor 182 and a lower transistor 180 with a sacrificial material (e.g., sacrificial material 630 and 632), the upper transistor being over the lower transistor. At block 904, the method 900 includes annealing the upper and lower transistors (e.g., top device 682 and bottom device 680), and replacing the sacrificial material (e.g., sacrificial material 632) of the upper transistor 182 with a first work function material (e.g., top work function material 132) at block 906. At block 908, the method 900 includes forming a trench (e.g., gate connection opening 650A, 650B, 650C, and 650D) exposing a sidewall 670 of the first work function material and a portion of the sacrificial material 630 of the lower transistor (e.g., bottom device 680). At block 910, the method 900 includes replacing the sacrificial material 630 of the lower transistor 180 with a second work function material (e.g., bottom work function material 130), so as to form a liner (e.g., conductive liner 160) of the second work function material in the trench. At block 912, the method 900 includes filling the trench with a fill material (e.g., fill material 162 and 362).

The liner (e.g., conductive liner 160) of the trench is in contact with the sidewall 670 of the first work function material (e.g., top work function material 132). The liner (e.g., conductive liner 160) extends a height (e.g., height H1) of the first work function material or the liner extends a partial height (e.g., less the entirety of the height H1) of the first work function material (e.g., top work function material 132), and the liner extends from the lower transistor 180 to the upper transistor 182. The fill material is different from the second work function material, the fill material being a conductive material (e.g., fill material 162) or a dielectric material (e.g., fill material 362). The lower transistor includes the fill material (e.g., the fill material 162 forms surrounding structures 402) disposed around a combination of channel regions (e.g., semiconductor layers 110) and a portion of the second work function material (e.g., bottom work function material 130).

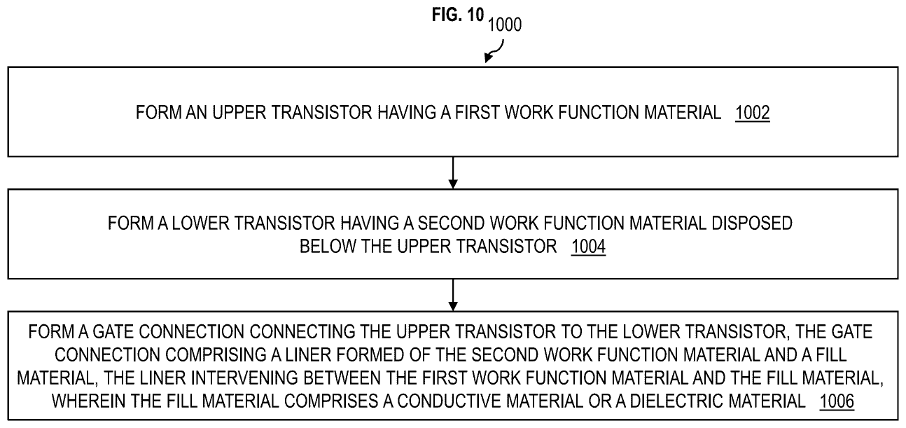

FIG. 10 a flowchart of a computer-implemented method 1000 of forming a semiconductor structure with stacked transistors having a gate connection according to one or more embodiments. Reference can be made to any figures discussed herein.

At block 1002, the method 1000 includes forming an upper transistor 182 having a first work function material (e.g., top work function material 132). At block 1004, the method 1000 includes forming a lower transistor 180 having a second work function material (e.g., bottom work function material 130) disposed below the upper transistor 182. At block 1006, the method 1000 includes forming a gate connection (e.g., gate connections 170 and 370) connecting the upper transistor 182 to the lower transistor 180, the gate connection including a liner (e.g., conductive liner 160) formed of the second work function material and a fill material, the liner intervening between the first work function material (e.g., top work function material 132) and the fill material, where the fill material includes a conductive material (e.g., fill material 162) or a dielectric material (e.g., fill material 362).

As discussed herein, gate material is formed around the semiconductor layers. The gate material includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Although not shown in detail, contact formation and ILD formation are performed. As such, ILD material can be deposited, source/drain contact openings are patterned by conventional lithography, and then metal is deposited to fill the cavities thereby forming metal contacts. A portion of the metal contacts may include silicide, resulting from the interface of the metal material and semiconductor material. The metal contacts are source/drain contacts that are respectively connected to epitaxial source/drain regions.

The ILD material can be SiO₂, SiN, a low-k dielectric material or an ultra-low-k dielectric material. Low-k dielectric materials may generally include dielectric materials having a k value of about 3.9 or less. The ultra-low-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulﬁdization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed.

Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for the purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc.

The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
an upper transistor having a first work function material disposed over a lower transistor having a second work function material; and
a gate connection connecting the first work function material to the second work function material, the gate connection comprising a liner formed of the second work function material.

2. The semiconductor structure of claim 1, wherein the liner of the gate connection is in contact with a sidewall of the first work function material.

3. The semiconductor structure of claim 1, wherein the liner extends a height of the first work function material.

4. The semiconductor structure of claim 1, wherein the liner extends a partial height of the first work function material.

5. The semiconductor structure of claim 1, wherein the liner extends from the lower transistor to the upper transistor.

6. The semiconductor structure of claim 1, wherein the gate connection comprises a fill material different from the second work function material.

7. The semiconductor structure of claim 1, wherein the gate connection comprises a fill material different from the second work function material, the fill material being a conductive material.

8. The semiconductor structure of claim 1, wherein the lower transistor comprises a fill material disposed around a combination of channel regions and a portion of the second work function material.

9. The semiconductor structure of claim 1, wherein the gate connection comprises a fill material different from the second work function material, the fill material being a dielectric material.

10. A method comprising:
providing an upper transistor having a first work function material disposed over a lower transistor having a second work function material; and
forming a gate connection connecting the first work function material to the second work function material, the gate connection comprising a liner formed of the second work function material.

11. The method of claim 10, wherein the liner of the gate connection is in contact with a sidewall of the first work function material.

12. The method of claim 10, wherein the liner extends a height of the first work function material.

13. The method of claim 10, wherein the liner extends a partial height of the first work function material.

14. The method of claim 10, wherein the liner extends from the lower transistor to the upper transistor.

15. The method of claim 10, wherein the gate connection comprises a fill material different from the second work function material.

16. The method of claim 10, wherein the gate connection comprises a fill material different from the second work function material, the fill material being a conductive material.

17. The method of claim 10, wherein the lower transistor comprises a fill material disposed around a combination of channel regions and a portion of the second work function material.

18. The method of claim 10, wherein the gate connection comprises a fill material different from the second work function material, the fill material being a dielectric material.

19. A method comprising:
forming an upper transistor and a lower transistor with a sacrificial material, the upper transistor being over the lower transistor;
annealing the upper and lower transistors;
replacing the sacrificial material of the upper transistor with a first work function material;
forming a trench exposing a sidewall of the first work function material and a portion of the sacrificial material of the lower transistor;
replacing the sacrificial material of the lower transistor with a second work function material, so as to form a liner of the second work function material in the trench; and
filling the trench with a fill material.

20. The method of claim 19, wherein the liner of the trench is in contact with the sidewall of the first work function material.

21. The method of claim 19, wherein:
the liner extends a height of the first work function material or the liner extends a partial height of the first work function material; and
the liner extends from the lower transistor to the upper transistor.

22. The method of claim 19, wherein the fill material is different from the second work function material, the fill material being a conductive material or a dielectric material.

23. The method of claim 19, wherein the lower transistor comprises the fill material disposed around a combination of channel regions and a portion of the second work function material.

24. A semiconductor structure comprising:
an upper transistor having a first work function material disposed over a lower transistor having a second work function material; and
a gate connection connecting the upper transistor to the lower transistor, the gate connection comprising a liner formed of the second work function material and a fill material, the liner intervening between the first work function material and the fill material, wherein the fill material comprises a conductive material or a dielectric material.

25. A method of forming a semiconductor structure comprising:
forming an upper transistor having a first work function material;
forming a lower transistor having a second work function material disposed below the upper transistor; and
forming a gate connection connecting the upper transistor to the lower transistor, the gate connection comprising a liner formed of the second work function material and a fill material, the liner intervening between the first work function material and the fill material, wherein the fill material comprises a conductive material or a dielectric material.
